(19) United States
(12) Patent Application Publication
(10) Pub. No.: US 2026/0280228 A1
(43) Pub. Date: Sep. 17, 2026

(54) LASER DIODE DRIVER AND METHOD FOR OPERATING AN OPTOELECTRONIC COMPONENT

(71) Applicant: OSRAM GmbH, Muenchen (DE)

(72) Inventor: Michael Boenigk, Berlin (DE)

(21) Appl. No.: 19/469,245

(22) PCT Filed: Mar. 22, 2024
(86) PCT No.: PCT/EP2024/057874

§ 371 Date: Sep. 25, 2025

(30) Foreign Application Priority Data
Mar. 30, 2023 (DE) 10 2023 108 243.4

(51) Int. Cl. H01S 5/042

(52) U.S. Cl. CPC H01S 5/042

(57) ABSTRACT

In an embodiment a driver includes a controllable current path configured for controlling an optoelectronic component, the controllable current path connected between a supply potential terminal and a reference potential terminal and including a controllable analog current source and a pair of terminals connected in series to the controllable analog current source, an analog current controller including a control input configured for detecting a signal derived from a current of the controllable current path, a control output connected to the controllable current source configured for setting the current of the current path, and a setpoint input configured for setting a setpoint value of the current of the current path.

### CROSS-REFERENCE TO RELATED APPLICATIONS

This patent application is a national phase filing under section 371 of PCT/EP2024/057874, filed Mar. 22, 2024, which claims the priority of German patent application no. 10 2023 108 243.4, filed Mar. 30, 2023, each of which is incorporated herein by reference in its entirety.

### TECHNICAL FIELD

The present invention relates to a laser diode driver and a method for operating an optoelectronic component, in particular a high-current laser diode.

### BACKGROUND

Laser diodes are often used in what is known as PWM operation. For this purpose, the laser diode or semiconductor laser is arranged in a current path which is switched on and off in pulses.

An essential criterion for pulsed operation in the high-current range is the edge steepness of the laser diode current. Since high-power laser diodes and high-power semiconductor lasers are particularly sensitive to overcurrents or current peaks (risk of destruction), a correspondingly delicate control system is necessary. In order to prevent overshoots or current peaks during switch-on, i.e., at the switching edge of a supply current for the laser diode, the controller must comprise a correspondingly high (slow) control time constant. However, this limits the maximum achievable edge steepness and thus also the switching frequency. In particular for high currents when supplying high-power laser diodes, the implementation also generates increased line inductance between the output of the current driver and the input of the high-power laser diode, which further reduces the edge steepness.

Some conventional LED current drivers with clocked arrangements (clocked current driver, switching regulator) use what is known as parallel FET dimming to increase the edge steepness. In addition to the actual switching regulator and the laser diode, a parallel arrangement is created which bridges or releases the required current through the laser diode. Although this results in significantly steeper switching edges for the current pulses, it also leads to overshoots and current peaks that are difficult to control. These overshoots and current peaks can damage the laser diode and should therefore be avoided. To attenuate the overshoots and current peaks, the control time constant can be slowed down, but this in turn reduces the edge steepness.

Due to the high sensitivity of laser diodes to current spikes, the above-mentioned circuit approach from the field of LED drivers is not possible or only possible to a limited extent for laser diodes. For this reason, analog current sources with analog current control circuits are often used for laser diodes, as these allow better control, particularly of the rising edge of a current pulse.

Although circuits for fast, essentially overshoot-free switching of laser diodes in the MHz range are commercially available, such arrangements are only suitable for low supply currents, i.e., currents below 1 ampere. They cannot be used for applications with higher supply currents, or the existing solutions again show only a low edge steepness during switching operations. Here, too, the problem arises that a reduction in the time constants of the analog current controller (i.e., faster settling) causes current peaks in the pulse edge, which lead to damage to the high-power laser diode.

### SUMMARY

Embodiments provide a laser diode driver that is suitable for high-current applications and also generates edges with increased steepness without major current peaks or overshoots.

Embodiments provide that, in an analog approach, i.e., an analog current source, the desired results can be achieved by using a switchable network with an additional current-independent element in parallel with the laser in a regulated current path for supplying a high-power laser. This achieves a significant increase in the switching edge. The improvement in the steepness of the switching edge is up to a factor of 100 higher, without any major overshoots or current peaks occurring. In addition, the proposed principle can be used to generate a bias voltage for the analog current controller (bias current) so that the semiconductor laser to be supplied with current is operated below its laser threshold, resulting in an additional improvement in switching speed.

The proposed principle thus allows a high edge steepness even with analog laser diode drivers for high-power laser applications. In addition, the control time constant of the analog current regulator is decoupled from the edge steepness of the generated pulse, so that both can be optimized independently of each other. In addition, the proposed arrangement allows peak current limiting to be generated at the moment of switch-on, which further protects the component, i.e., the high-power laser diode.

In one embodiment of the proposed principle, a laser diode driver comprises a controllable current path connected between a supply potential terminal and a reference potential terminal. The controllable current path comprises a controllable analog current source and a pair of terminals connected in series thereto for an optoelectronic component. The term “optoelectronic component” refers in particular to a semiconductor laser, a laser diode, or a VCSEL for the present application. In particular, this shall include the respective high-power forms that are suitable for operation with a supply current greater than 1 A. In the following, the terms semiconductor laser or laser diode are therefore used synonymously for the various possible designs.

The laser diode driver comprises an analog current controller with a control input for detecting a signal derived from a current along the controllable current path. This can be, for example, a voltage signal which is tapped via a current-voltage converter. The analog current controller comprises a control output that is connected to the controllable current source for setting the current through the current path and thus through the optoelectronic component. In addition, a setpoint input is provided for setting a setpoint value for the current through the current path.

The analog current controller is thus designed to control a current through the controllable current path and thus the optoelectronic component based on the setpoint value applied to the control input. The control time constant of the analog current controller depends on a charge storage device coupled to the control output.

According to the proposed principle, the laser diode driver also includes a switching input for supplying a switching signal to a bypass circuit arranged parallel to the terminal pair. The bypass circuit serves to decouple (bypass) the optoelectronic component from the current path or to switch it into the current path (enable it), depending on the switching signal, without causing a current interruption in the current path.

In this way, the optoelectronic component or semiconductor laser can be switched into or disconnected from the current path at high speed, i.e., significantly faster than the control time constant of the analog current controller.

According to embodiments of the invention, a nonlinear component is now connected to the bypass circuit to avoid possible overshoots and current peaks during the switching process. The nonlinear component is designed in such a way that the voltage drop across the bypass circuit and the component is essentially independent or only slightly dependent on the current flowing through the bypass circuit. In contrast to conventional approaches, in which a resistor is used, for example, this allows the behavior of the laser diode to be replicated. The bypass circuit thus enables fast switching, as the analog current regulator no longer has to settle completely, as is the case in conventional implementations. In this respect, a current pulse is no longer dependent on the control time constant, but primarily on the behavior of the bypass circuit. Since this can be switched on and off more quickly, significantly steeper edges are generated for a corresponding current pulse by adding or disconnecting the bypass circuit.

The approach used here thus provides a regulated analog current source for high-power laser diodes that offers a high switching edge steepness and is simultaneously decoupled from the control time constant. The bypass circuit achieves better settling behavior at the moment of release, and despite the high edge steepness, there is no current spike in the switch-on current that could damage the laser diode. Another advantage is that it comprises the simple provision of a bias current.

In some embodiments, the nonlinear component comprises at least one diode connected in the forward direction. The operating voltage of this diode connected in the forward direction essentially determines the voltage drop, provided that there are no other elements in the bypass circuit that generate resistance. In this context, several diodes can thus be easily connected in the forward direction to generate a suitable (higher) bias voltage for the component connected between the terminals.

Alternatively, one or more Zener diodes connected in reverse direction can also be used. However, these Zener diodes must absorb the current flowing through the bypass circuit, so their current carrying capacity must be significantly greater than that of low-power Zener diodes.

Alternatively, transistors such as bipolar or field-effect transistors can also be used to generate a voltage drop that is essentially independent of the current flow. For this purpose, the base terminal of a bipolar transistor can be coupled to its collector or emitter terminal. In a field-effect transistor, its gate is coupled to one of the two other channel terminals so that the voltage across the channel is kept constant. The same can also be done for bipolar transistors. The coupling can be direct or via additional elements such as voltage dividers, resistors, etc.

In some respects, the nonlinear component is implemented in such a way that the voltage drop generated across the parallel bypass circuit, and thus in particular the voltage drop across the component, is lower than the operating voltage of the optoelectronic component connected to the terminal pair. In other words, the optoelectronic component is also operated in a switched-off state, i.e., with an activated and parallel-connected bypass circuit below its operating voltage or operating current. The optoelectronic component, for example in the form of a semiconductor laser diode, can thus be maintained in a state below its threshold voltage or laser threshold current, so that when it is switched on again later, this process takes place more quickly and with a greater edge steepness. Overall, this also improves the edge steepness of the optical pulse.

Some embodiments deal with the activation or deactivation of the analog current controller in order to ensure a reduction in overall energy consumption. In some embodiments, this can be achieved, for example, by means of a corresponding circuit that switches a longitudinal control transistor in the current path, i.e., the controllable current source, on or off.

Alternatively, it is also possible to set the setpoint value at the input to zero so that the current controller regulates downwards. Alternatively, it is also possible to interrupt the laser diode current by means of a further switching element arranged in series with the optoelectronic component and the bypass circuit. As a further alternative, the analog current controller can be operated continuously, and the component connected to the terminal pair is switched on or off only at the switching input, i.e., with the aid of the bypass circuit.

Some other embodiments relate to the design of the laser diode driver. This is designed in such a way that the switching signal is only provided after a setpoint has been applied and the analog current controller has been regulated. This ensures that the switching signal is only provided after the settling time of the analog current controller, when it is active in its regulation. This prevents oscillations during the settling time.

In this context, the analog controllable current source is designed to provide a current signal in the range of greater than 1 ampere, for example for pulsed operation, in which a current through the optoelectronic component is in the range of 1 ampere to 10 amperes. However, the proposed principle is not limited to this, but the improved edge steepness can be available both for high-power laser diodes with supply currents of more than 1 ampere and for laser diodes with lower supply currents and significantly higher switching times.

According to the proposed principle, in some embodiments, the edge steepness of a current along the controllable current path through the optoelectronic component is essentially determined by a voltage drop across the bypass circuit arranged parallel to the terminal pair.

Another embodiment concerns a method for operating an optoelectronic component, in particular a semiconductor laser or a high-power laser diode. The optoelectronic component is arranged in a controllable current path.

The method comprises the steps of providing a current setpoint and subsequently controlling a current through the current path to the current setpoint. However, the optoelectronic component is bypassed by a bypass circuit arranged in parallel, and the current is essentially conducted through this bypass circuit.

The voltage drop across the bypass circuit is essentially independent or only slightly dependent on the current flowing through the bypass circuit. Once the current has been regulated to the current setpoint, the parallel bypass circuit is disconnected so that the current now flows through the optoelectronic component or semiconductor laser. In general, this switching process changes the load conditions in the regulated current path and the controller must readjust. However, the controller now starts from a pre-regulated level that is as close as possible to the setpoint.

In order to ensure correct shutdown of the optoelectronic component in a parallel bypass circuit, it is intended in some embodiments that the voltage drop across the bypass circuit is smaller than the operating voltage of the optoelectronic component.

In some embodiments of the proposed method, the voltage drop is generated by a nonlinear component, among other things. The voltage drop is essentially caused by this component, although other elements of the bypass circuit may also contribute to it. In some embodiments, the nonlinear component comprises at least one or more diodes connected in the forward direction. Alternatively, one or more Zener diodes connected in reverse direction can also be used. As already explained above, it is also possible to provide transistors, for example in the form of bipolar or field-effect transistors, whose respective base or gate connection is coupled to one of the other connections.

The proposed principle decouples the control time constant of the analog control from the transient response when a pulse is applied, i.e., the edge steepness. This allows the control time constant to be set independently of the edge steepness. In some respects, the control time constant is determined by the capacitance of a charge storage device. The edge steepness during a switching operation is in turn essentially determined by a voltage drop across the bypass circuit.

### BRIEF DESCRIPTION OF THE DRAWINGS

Further embodiments and embodiments according to the proposed principle will become apparent in relation to the various embodiments and examples described in detail in connection with the accompanying drawings.

FIGS. 1A and 1B show a time curve of the laser diode current for a switch-on operation with conventional analog current drivers;

FIG. 2 shows a time curve of the laser diode current for a pulse as it can be generated with conventional analog driver circuits;

FIG. 3 shows a first embodiment of a laser diode driver according to the proposed principle;

FIG. 4 shows a second embodiment of a laser diode driver according to the proposed principle;

FIG. 5 is a third embodiment of a laser diode driver according to the proposed principle;

FIG. 6 shows a time curve of the laser diode current, in particular the rise time with a driver based on the proposed principle ;

FIG. 7 shows a time curve of the laser diode current for a fast pulse generated by a driver based on the proposed principle;

FIG. 8 shows examples of the signal curves for the switching signal, the control signal, and the current through the laser diode according to a design with some embodiments of the proposed principle;

FIG. 9 is a pulse sequence with a set bias current;

FIG. 10 shows a design of the proposed method; and

FIG. 11 shows a design of another non-linear component.

### DETAILED DESCRIPTION OF ILLUSTRATIVE EMBODIMENTS

The following embodiments and examples show various embodiments and combinations thereof according to the proposed principle. The embodiments and examples are not always to scale. Likewise, various elements may be enlarged or reduced in size to highlight individual embodiments. It goes without saying that the individual embodiments and features of the embodiments and examples shown in the figures can be readily combined with each other without compromising the principle of the invention. Some embodiments comprise a regular structure or shape. It should be noted that in practice, slight deviations from the ideal shape may occur without contradicting the inventive idea.

Furthermore, the individual figures, features, and embodiments are not necessarily shown in their correct size, and the proportions between the individual elements do not necessarily have to be correct. Some embodiments and features are emphasized by being shown enlarged. However, terms such as “above,” “above,” “below,” “below,” “larger,” “smaller,” and the like are correctly represented in relation to the elements in the figures. This makes it possible to infer such relationships between the elements from the illustrations.

Clocked current converter circuits are often used to operate light-emitting diodes (not necessarily the laser diodes intended in this application). If these LEDs are operated in a pulsed manner, this is achieved by switching the converter on and off. However, this means that the pulse frequencies are limited by the switching edges and the control time of the converter. In order to increase the edge steepness in clocked current converters, various measures can be specified, but these often lead to corresponding overshoot in the pulse sequence, i.e., current peaks in the supply current of the LED due to the settling time and the control of the converter.

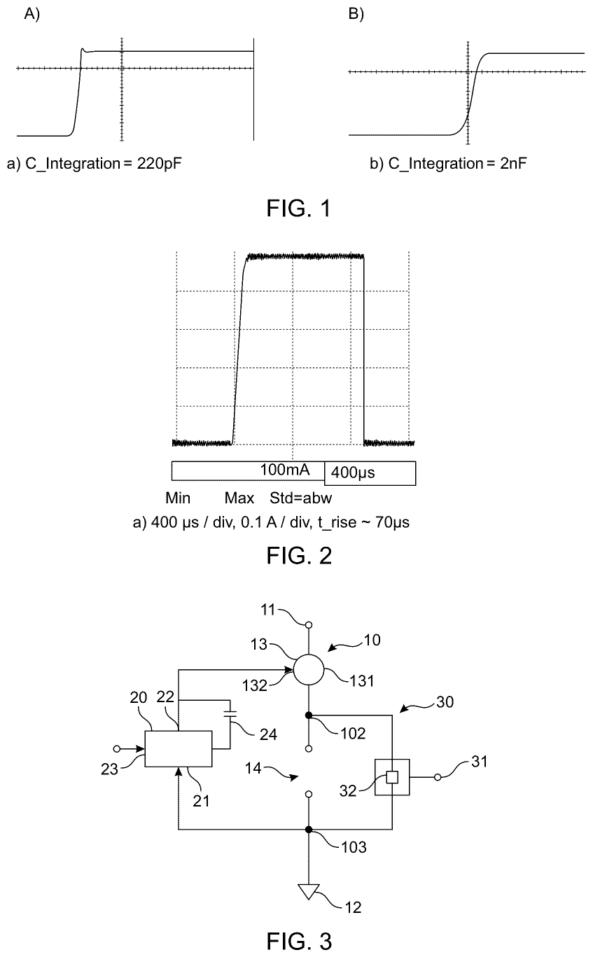

To avoid overshoots and current peaks during the operation of laser diodes, analog constant current controllers are preferred. One component of the controller plays an important role here, namely the integration capacitor, which significantly determines the settling time. FIG. 1A and B, as well as FIG. 2, show recordings from an oscilloscope that depict the rise of such a pulsed laser diode current depending on this capacitor.

In subfigure A, the so-called integration capacitor of the current regulator is relatively small. This results in a steeper rise time, which, however, leads to a slight overshoot, i.e., a current peak, in the upper range. The term overshoot refers to an excessive current and/or voltage component that results from the control and the associated control time constants. The peak results from the behavior of the controller and is also dependent on parasitic effects such as stray capacitances and stray inductances, among other things. Although these can be reduced by good circuit board layout, the components resulting from the design of the circuit and, in particular, the laser diode leads remain.

Although the current peak is relatively small in FIG. 1A and amounts to only a few percent of the total value, this can lead to damage to the laser diode during the switching process. While LEDs are more robust in this respect, high-current laser diodes in particular are very sensitive to these current peaks. The reason for this is the direct dependence of the laser output power on the supply current. A current spike leads directly to a sharp increase in laser power, which can quickly damage the resonator. The problem is particularly acute when the laser diode is already operating at the upper end of its power range.

To prevent overshoot as shown in subfigure A, it is possible, for example, to increase the control time of the current controller, which can be achieved by increasing the capacity of the integration capacitor. This is shown in FIG. 1B. However, it is clear here that the rise time also increases by at least the same factor as a result.

FIG. 2 shows an actual pulse recorded in an oscilloscope whose time axis comprises a time setting of 400 μs per division. This results in a rise time in the range of approximately 70 μs, which essentially corresponds to the curve shown in FIG. 1B. Although the rise time may be sufficient for normal lighting applications, the edge steepness 2 is too high for higher switching frequencies.

Although the two embodiments of a high switching frequency and a high edge steepness can be achieved to a certain extent in more complex analog current control circuits for low currents, these controls do not generate the desired current levels for high-current applications, especially for supplying high-power laser diodes with currents in the ampere range.

The inventor has now discovered that, in analog current sources for high-current laser diodes, a parallel network can be connected to the current path to be regulated, which can be used to achieve a significant increase in the switching edge without, however, generating the undesired current peaks that are not. This improvement is even better than that achieved with conventional clocked converters, which already operate at high switching frequencies and steep switching edges.

This is achieved by means of a bypass circuit forming the network, which is connected in parallel to the laser diode (or, in general, an optoelectronic component) used. In addition to an element for activating or deactivating the bypass circuit as such, the bypass circuit also has a nonlinear component that generates a voltage drop that is essentially independent of the current. The nonlinear component is, for example, a diode whose operating voltage and voltage drop are essentially independent of the current, or show only a slight current dependence in the forward direction.

FIG. 3 shows an example of a laser diode driver based on the proposed principle.

The laser diode driver, which is designed as an analog current source, comprises a controllable current path 10, which is connected between a supply potential connection 11 and a reference potential connection 12. In this embodiment, a controllable analog current source 13 is provided, which is connected on the input side to the supply potential terminal 11 and provides a current dependent on a control signal 132 at its output 131. The output 131 of the current source is connected to the tap 102 and the terminal pair 14. The tap 102 or 103 is also connected to the bypass circuit 30, which thus bypasses the terminal pair 14 and the laser diode 14a.

For this purpose, the bypass circuit comprises a switching input 31 and a nonlinear element 32, so that the latter can be connected in a separable manner between the two taps 102 and 103 by means of a switching signal PWM_{_fast} at the switching input 31. This allows the nonlinear element₃₂ to be connected in ₚₐᵣₐₗₗₑₗ with the terminal pair₁₄can be used to connect the nonlinear element 32 in parallel to the terminal pair 14. The second tap 103 leads on the one hand to an unshown resistor (which can also be omitted) connected to a reference potential terminal 12, and on the other hand to the feedback input 21 of an analog (P)I(D) controller 20.

The analog controller 20 also has a setpoint input 23 for setting a current through the controllable current source 13 by means of a setpoint signal MOD_LD1. For this purpose, the analog controller is also equipped with a charge storage device in the form of a capacitor 24, which is connected between the controller output 22 and a feedback input. The capacitor 24 thus corresponds to the integration capacitor in the preceding FIGS. 1A and 1B.

When this arrangement is in operation, a signal dependent on a setpoint signal at input 23 is generated at the control output 22 and fed to the controllable current source 13. Based on this, the controllable current source generates a corresponding current signal at its output 131. This is held at a setpoint by the control of the (P)I(D) controller 20.

The control time constant for such a control is essentially dependent on the size of the capacitor 24. In an initial operating state according to the proposed principle, the control signal is generated at output 22, while at the same time the terminal pair 14 with a high-power laser diode connected between them is bridged by the parallel-connected bypass circuit 30. The current supplied by the current source 13 initially flows through the nonlinear element 32, thereby generating a voltage drop that is essentially independent of the current.

Only after the settling time of the controller 20, i.e., when it provides stable and continuous control to the setpoint (defined at the setpoint input 23), is a switching signal applied to input 31, thereby disconnecting the bypass circuit 30 from terminal pair 14. As a result, the current now flows through the laser diode and along the terminal pair 14. The current regulator now adjusts to the new load conditions. However, due to the existing previous bypass circuit 30, the current regulator is biased, i.e., it is closer to its operating point than when switched on without the previous load through the bypass circuit. At the same time, the switching process in the bypass circuit 30 can be optimized, allowing the rise time to be adjusted to the desired parameters.

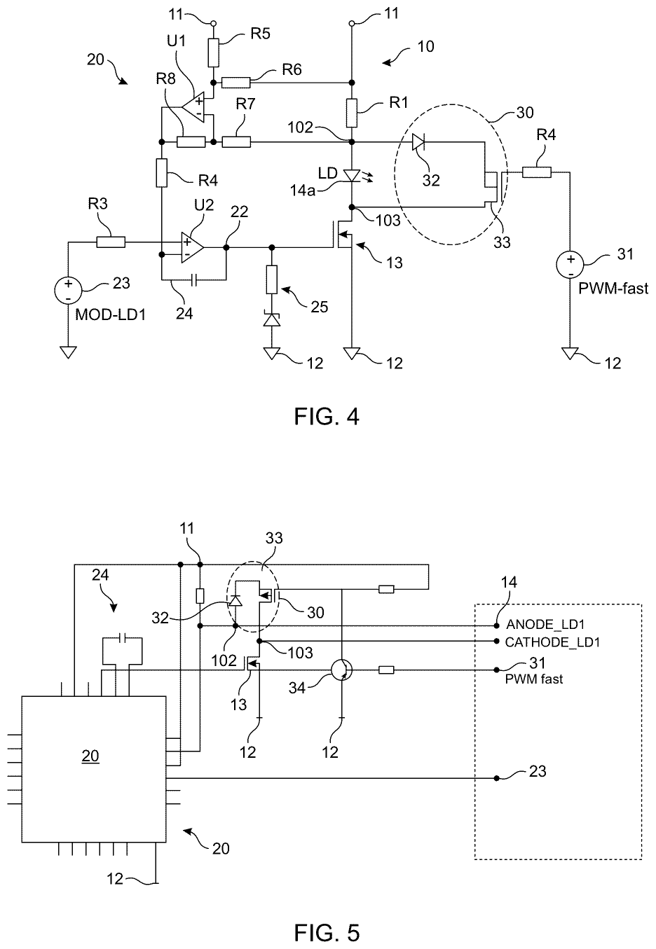

FIG. 4 shows another design of a laser diode driver with discrete components. The current path 10 is connected between the supply potential connection 11 and the reference potential connection 12 and comprises a resistor R1, the tap 102, a laser diode 14a connected to the terminal pair 14, a longitudinal control transistor, which forms the controllable current source 13, and the reference potential connection 12. A diode 32 is connected between the taps 102 and 103 as a nonlinear element, and a control transistor 33 is connected as a MOSFET. The two elements 32 and 33 form the bypass circuit, with the control terminal of the transistor 33 connected to the switching input 31 via a resistor R4.

In this embodiment, the analog current regulator 20 comprises two interconnected operational amplifiers U1 and U2. A current setpoint signal from the setpoint input 23 is fed to the non-inverting input of the operational amplifier U2 via a resistor R3. The inverting input of operational amplifier U2 is coupled to its output via an integrating charge storage device 24, which also forms the control output 22 and is connected to the control terminal of the controllable current source 13. In addition, the control output 22 is connected to an optional control limiter 25, which consists of a resistor connected between the reference potential terminal 12 and a diode connected in reverse direction. The control limiter 25 limits the current downwards during control.

The analog current controller also comprises a first operational amplifier U1, the output of which is connected to the inverting input of the second operational amplifier U2 via a resistor R4. At the same time, this resistor R4 is also connected to the integrating charge storage device 24.

On the input side, the operational amplifier U1 is connected via a voltage divider consisting of resistors R5 and R6 to the supply potential connection 11, while the non-inverting input of U1 leads via a voltage divider R7 and R8 on the one hand to the output of the operational amplifier U1 and on the other hand to the tap 102. The operational amplifiers U1 and U2 thus form a control system for adjusting the longitudinal control transistor 13.

In one operation, a voltage signal is fed to the input of the first operational amplifier U1 via resistor R1, which essentially corresponds to the current flowing through resistor R1. The output signal is fed to the inverting input of the second operational amplifier U2, to which the setpoint is fed via the setpoint input 23. The output 22 of the operational amplifier U2 is fed to the control transistor 13, which now regulates the current through the resistor R1 and thus also through the laser diode 14a based on the control signal at the output 22. This operating procedure essentially corresponds to the steady state, in which the current through the current path 10 is set by the analog controller 20 depending on the setpoint signal at the non-inverting input of the operational amplifier U2.

For the switch-on and switch-off processes, the rise time and also the fall time are essentially dependent on the integrating capacitor 24 between the inverting input of the second operational amplifier U2 and the output 22. A smaller capacitor value leads to higher overshoots, both during the rise and during the fall. To avoid overshoots, larger capacitors 24 can be used, but these in turn increase the rise time. According to embodiments of the invention, a bypass circuit 30 is therefore provided, which is connected between the terminals 102 and 103.

When the laser diode is switched on, the proposed principle now involves a first step of setpoint control, in which the current setpoint signal is applied to the position input 23. At the same time or shortly before, a switching signal is also fed to the switching input 31 of the bypass circuit 30, which activates the switching transistor 33 of the bypass circuit 30 and thus switches the nonlinear element in the form of the diode 32 between the terminals 102 and 103, aligning it in parallel with the laser diode 14a. (The signal logic can also be reversed by selecting a suitable n- or p-MOSFET so that the current flows regularly through the diode and the bypass circuit is only deactivated when the MOSFET is activated.)

The laser diode 14a is thereby bypassed, whereby a voltage drop across the bypass circuit depends mainly on the forward voltage through the diode 32. The analog current controller now regulates the current signal flowing through the current path 10 and diode 32 to the setpoint value based on the signal at the setpoint input 23 and the control signal at input 31. Once this process is complete, i.e., the analog current controller has stabilized, the switching signal at input 31 can be deactivated so that the bypass circuit is opened and the current flows through the laser diode.

This process is shown in FIG. 8. The signal PWM_{_fast}is the signal fed to the switching input 31, the signal MOD_LD1 is the setpoint signal for the analog current controller, and the signal I_LD1 corresponds to the current signal through the laser diode.

As can be seen, the setpoint signal MOD_LD1 is activated first at time T1, whereby the switching signal and the bypass circuit are designed in such a way that the laser diode is bypassed, so that the current through the laser diode is essentially zero or corresponds to a bias current. After a settling process of the analog current driver during the period t(_{v),}the bypass circuit is disconnected (PWM(_{_fast)}goes from “low” to “high”), so that the current I_LD1 through the laser diode increases with a very short rise time. If the time tv for the settling process of the current controller 20 is shorter than the off time until the next switching signal (PWM(_{_fast}) to “high”), both the setpoint signal MOD_LD1 and as well as the switching signal PWM(_{_fast}) can be switched off simultaneously, thereby switching off the current through the laser diode.

At time T2, the setpoint signal MOD_LD1 is activated again, but this time with a lower value, so that the total current I_LD1 is set to a lower level.

In this embodiment, the bypass circuit is switched on in such a way that the switching signal at switching input 31 is again deactivated, thereby bypassing the laser diode. Only after the controller has settled is the bypass circuit switched off and the current I_LD1 flows through the laser diode at a lower level. If slight modulation of the current is necessary, this can be done with the controller via the setpoint signal. To switch off the current through the laser diode, in this embodiment the switching signal PWM(_{_fast)}is first deactivated and only after the time t(ᵥ₎has elapsed is the setpoint signal MOD_LD1 set to 0.

In some embodiments, especially with a laser with very fast switching frequencies, the control time tv of the analog current controller may be greater than the actual pulse duration of the laser diode. For example, the rise times shown in FIG. 2 prohibit switching speeds with pulses of more than 100 kHz.

In this case, it is advisable to leave the analog current control driver permanently activated and to generate an on-off control of the current through the laser diode solely by means of the signal PWM_{_fast} at switching input 31. This is shown in the last section of FIG. 8 from time T3 onwards. The individual pulses have a shorter length than the time duration tv.

Only with the last falling clock edge of the PWM(_{_fast)}signal can the setpoint signal MOD_LD1 also be switched off. In this way, high rise and fall times are achieved at high switching frequencies.

FIG. 5 shows a further design in which the analog current control driver is provided as an integrated component. Externally, only the series control transistor for current source 13, the integral capacitor 24 for setting the control time constants, and the bypass circuit 30 are provided externally for this component.

The embodiment also specifies a bipolar transistor 34 whose base connection is connected via a resistor to the switching input 31 for the fast switching signal PWM_{_fast}. For the fast switching operation, the bipolar transistor 34 is switched on so that the control terminal of the switching transistor 33 is pulled to the reference potential 12 via a further resistor. This activates or deactivates the bypass circuit accordingly (negative logic compared to the switching signal PWM(_{_fast)} in FIG. 8). The actual current control to the setpoint is performed via connection 23, as in the previous embodiment, which is made available to the integrated circuit 20 as a setpoint input.

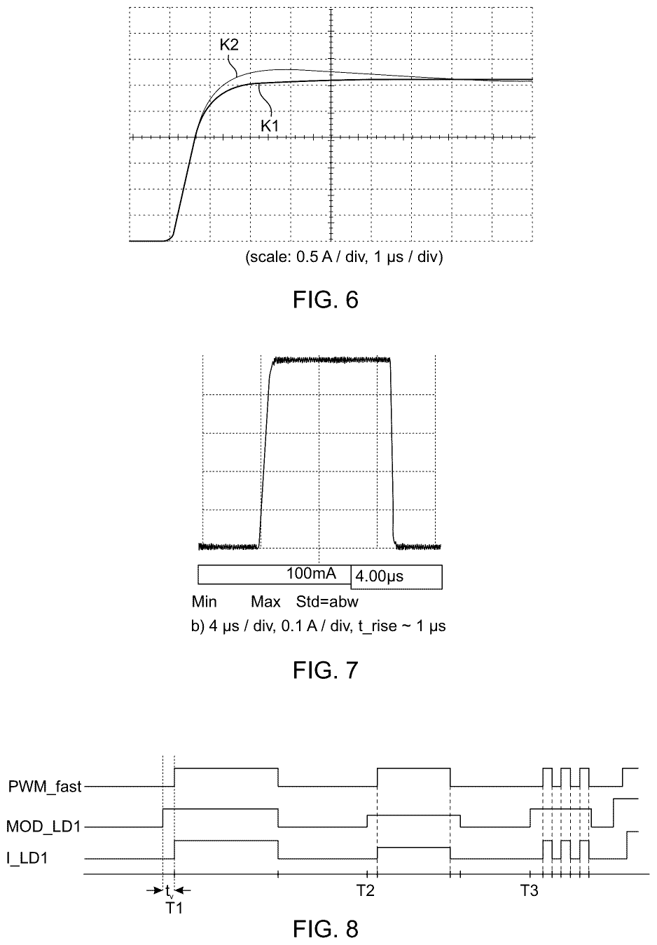

FIG. 6 now shows a temporal current curve and, in particular, the rise time with a driver based on the proposed principle.

Curve K1 corresponds to a rising pulse edge with an integration capacitor of approximately 2 nF, while curve K2 shows the rise time with an integration capacitor of 390 pF, i.e., approximately ⅕ times. The y-axis is scaled at 0.5 A per division, and the x-axis at 1 μs per division. The figure clearly shows that with a smaller integral capacitor, represented by curve K2, there is a slight overshoot, which no longer occurs with the larger integral capacitor of curve K1. In contrast, however, this integral capacitor has no major influence on the rise time, which essentially remains at around 1 μs between 10% and 80%. This means that, thanks to the additional measure of a bypass circuit, the rise time becomes essentially independent of the integration capacitor used to set the control time. This is advantageous because overshoot can now be reduced by increasing the control time without this having a negative effect on the rise time.

FIG. 7 shows a complete pulse with a length of approximately 10 μs, with the rise time being within approximately 1 μs. The fall time of this pulse is also approximately 1 to 1.5 μs, resulting in very steep pulse edges with a pulse duration of only 10 μs.

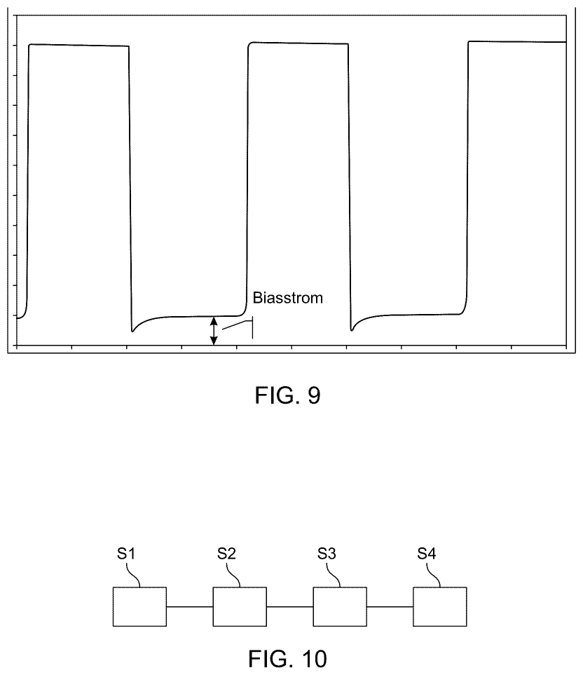

FIG. 9 also shows that these measures not only allow very steep pulse edges to be generated, but also that these can continue to be formed without overshoot even at very high currents. FIG. 9 shows three consecutive pulses with a pulse length of essentially 1 μs. The rise time is significantly less than one μs. In addition, there is a bias current here that corresponds to approximately 0.4 A and is caused by the diodes used in the forward direction in the bypass circuit.

This also allows a laser diode to be operated below its threshold current when switched off, so that it can be switched on particularly quickly, while the settling time of the controller is kept to a minimum. The bias current can be adjusted using the nonlinear elements used, for example, a diode or a transistor. In addition, the voltage drop of the nonlinear element should be below the threshold voltage of the high-power laser diode in order to ensure that the diode is switched off safely.

FIG. 10 shows an embodiment of a method for operating an optoelectronic component, and in particular a high-power semiconductor laser, which is arranged in a controllable current path.

In step S1, a current setpoint is provided for this purpose, which is used in step S2 to regulate a current through the current path to the setpoint. However, this control is performed in such a way that the optoelectronic component or high-power semiconductor laser to be operated in pulse mode is bypassed during this initial settling phase by a bypass circuit that is arranged and switched on for this purpose. As a result, the initial switch-on current flows essentially through the bypass circuit, whereby the voltage drop across this bypass circuit is essentially independent or only slightly dependent on the flowing current.

This behavior is achieved by a nonlinear element, for example, a diode in the forward direction or one or more Zener diodes or transistors. In the latter case, the control connection is connected in such a way that a current-independent resistance is obtained. The bypassing by means of the bypass circuit continues until the current control has stabilized. Only then is the parallel bypass circuit disconnected, allowing the current to flow through the optoelectronic component and thus the laser diode. This disconnection can be effected by a switching signal, which allows the laser diode to be switched on and off quickly without further overshoots being generated by the current control.

The proposed principle thus achieves a high edge steepness, especially for high-power laser diodes, which also allows high switching speeds in the range of a few microseconds to be achieved. The settling behavior is decoupled from the control time constant in terms of the rise time, so that both can be optimized independently of each other. In particular, despite the high edge steepness, there are no current peaks, so that the high-power laser diodes can be protected accordingly. With the appropriate use of a nonlinear component, a simple bias current can be achieved through the laser diode, so that the actual times for switching on the laser diode are also reduced here. In addition, peak current limiting takes place at the moment of switching on.

The laser diode driver used here and the proposed method can be used primarily for high-power laser diodes, for example in graphic head-up displays, holographic displays, or projectors. In addition, the arrangement also allows CW drivers to be modified for pulse operation, resulting in greater flexibility in the selection of existing drivers.

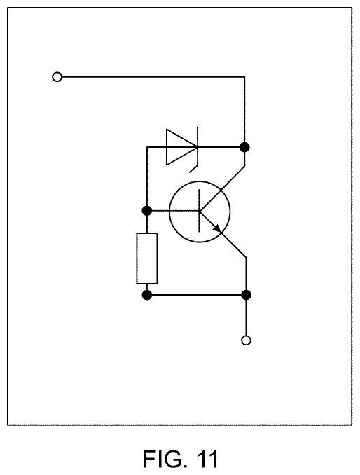

FIG. 11 shows a design of a non-linear component 32, which can be used instead of the diode 32 in the designs shown previously, for example.

The design shown is an npn bipolar transistor in which the base is connected to the collector terminal via a Z-diode as shown. A resistor is connected between the base and the emitter. In this design, the Z-diode generates a constant voltage drop across the collector-emitter path, which is determined by the Z-diode voltage. If the diode and resistor are omitted and the base is connected directly to the collector, a voltage drop is obtained which corresponds to the collector-emitter voltage when the transistor is fully conducted, i.e., approx. 0.7V. For pnp transistors, the base and collector can be swapped accordingly.

The design shown in FIG. 11 also works in principle with a field-effect transistor, since the voltage drop is determined by the properties of the diode.

1-14. (canceled)

15. A driver comprising:
a controllable current path configured for controlling an optoelectronic component, the controllable current path connected between a supply potential terminal and a reference potential terminal and comprising a controllable analog current source and a pair of terminals connected in series to the controllable current source;
an analog current controller comprising:
a control input configured for detecting a signal derived from a current of the controllable current path,
a control output connected to the controllable current source configured for setting the current of the current path, and
a setpoint input configured for setting a setpoint value of the current of the current path,
wherein a control time constant of the analog current controller is based on a charge storage device coupled to the control output;
a bypass circuit arranged in parallel with the pair of terminals; and
a switching input configured for supplying a switching signal to the bypass circuit,
wherein the bypass circuit comprises a nonlinear component.

16. The driver according to claim 15, wherein the nonlinear component is configured to cause a voltage drop that is independent of the current.

17. The driver according to claim 15, wherein the nonlinear component comprises:
at least one diode connected in a forward direction, and/or
at least one Zener diode connected in reverse bias, and/or
at least one bipolar transistor whose base terminal is coupled to one or more other transistor terminals, and/or
a field effect transistor whose gate is coupled to one or more other transistor terminals.

18. The driver according to claim 15, wherein a voltage drop across the bypass circuit is lower than an operating voltage of the optoelectronic component connected to the pair of terminals.

19. The driver according to claim 15, further comprising:
a shutdown transistor connected in the current path; and/or
a control limiter connected to the control output (22) the reference potential terminal.

20. The driver according to claim 15, wherein the bypass circuit comprises a switching transistor whose control terminal is suppliable with the switching signal.

21. The driver according to claim 15, wherein the driver is configured to provide the switching signal only after the setpoint is set or only after a settling time of the analog current controller.

22. The driver according to claim 15, wherein the controllable current source is configured to provide a current signal in a range greater than 1 A.

23. The driver according to claim 15, wherein a slope of the current of the controllable current path is determined by a voltage drop across the bypass circuit and/or the nonlinear component.

24. A method for operating an optoelectronic component arranged in a controllable current path, the method comprising:
providing a current setpoint;
regulating a current in the current path to the current setpoint, wherein the optoelectronic component is bypassed by a parallel bypass circuit so that the current flows through the bypass circuit, wherein a voltage drop across the bypass circuit is independent or only slightly dependent on the flowing current; and
disconnecting the bypass circuit after the current is regulated to the current setpoint.

25. The method according to claim 24, wherein a voltage drop across the bypass circuit is smaller than an operating voltage of the optoelectronic component.

26. The method according to claim 24, wherein the voltage drop across the bypass circuit is generated by a nonlinear component comprising:
at least one diode connected in a forward direction, and/or
at least one Zener diode connected in reverse direction, and/or
at least one bipolar transistor whose base terminal is coupled to one or more other transistor terminals, and/or a field-effect transistor whose gate is coupled to one or more other transistor terminals.

27. The method according to claim 24, wherein a control time constant is based on a capacitance of a charge storage device.

28. The method according to claim 24, further comprising determining a slope, while controlling the setpoint, by a voltage drop across the bypass circuit.
